(19) United States
(12) Patent Application Publication
(10) Pub. No.: US 2018/0018104 A1
(43) Pub. Date: Jan. 18, 2018

(54) DYNAMIC WRITE LATENCY FOR MEMORY CONTROLLER USING DATA PATTERN EXTRACTION

(71) Applicant: Advanced Micro Devices, Inc., Sunnyvale, CA (US)

(72) Inventors: Amin Farmahini Farahani, Sunnyvale, CA (US); Benjamin Y. Cho, Sunnyvale, CA (US); Nuwan Jayasena, Sunnyvale, CA (US)

(21) Appl. No.: 15/211,488

(22) Filed: Jul. 15, 2016

(51) Int. Cl. G06F 3/06; G11C 13/00

(52) U.S. Cl. CPC G06F 3/0611; G11C 13/0069; G06F 3/0659; G06F 3/0679

(57) ABSTRACT

Methods and apparatus of dynamically determining a variable reset latency time based on a data pattern of the data to be written into memory is disclosed. A memory controller determines a variable reset latency time for a plurality of memory cells depending on the bit values to be written into the plurality of memory cells in response to a write request having corresponding bit values. A write latency for the plurality of memory cells is dependent on the bit values being written into the plurality of memory cells. The memory controller writes the bit values of the write request to the plurality of memory cells within the determined variable reset latency time.

### GOVERNMENT LICENSE RIGHTS

This invention was made with government support under Prime Contract Number DE-AC52-07NA27344, Subcontract No. B608045 awarded by the Department of Energy (DOE). The government has certain rights in the invention.

### FIELD OF THE DISCLOSURE

The disclosure relates generally to memory controllers that read and write data to memory cells.

### BACKGROUND

Emerging non-volatile random-access memories, such as resistive random-access memory (ReRAM), phase-change memory (PCM), and spin-transfer torque magnetic random-access memory (STT-RAM), have wide applicability in computing systems. Such emerging non-volatile random-access memory technologies may replace existing technologies such as dynamic random access memory (DRAM) and solid state drive (SSD) or may enable additional capabilities in other memory technologies, such as persistent tiers of memory hierarchy. Unlike DRAM, which stores bit information in the form of electric charges, non-volatile random-access memory stores the bit information by altering properties (e.g., resistance, physical state, magnetic orientation) of a suitable material in each memory cell.

Specifically, non-volatile random-access memory may exhibit a crossbar structure as known in the art that includes memory cells at the intersection of word lines and bit lines, and the values ‘0’ and ‘1’ are stored in these memory cells by changing the properties of materials they use. For example, in some such memories, read operations occur by applying a certain amount of voltage across the memory cells and by sensing the voltage drop or current using a sense amplifier. A write operation occurs by applying a different voltage (typically a higher voltage than for reads) across the memory cells and includes two phases, a set and a reset, which have asymmetric latencies. This asymmetry comes from the fact that the reset phase requires higher voltage than the set phase. The set latency is typically tens of nanoseconds and does not vary much with the number of bits to set.

The reset latency exponentially increases as the number of bits to reset increases. The reset latency typically varies between few tens of nanoseconds to several hundred nanoseconds. In addition to the number of bits, the reset latency also depends on locations of memory cells. For instance, if a memory cell is farther from a voltage driver, it will suffer from larger voltage drop due to the wire resistance and sneak current that flows through inactivated bit-lines. Consequently, the voltage applied to the memory cell will be less than expected, and the write latency as a whole increases super-linearly as the number of bits to reset increases.

One of the advantages of non-volatile memory is its high density and low leakage power. The crossbar structure is a common form of structuring non-volatile memory cells for improving memory density. However, the crossbar structure in such non-volatile memory cells comes at the cost of higher reset latency and access energy because there are more paths for sneak currents and less voltage may be applied to memory cells. The amount of voltage applied to the memory cell determines the write latency because the voltage and write latency are inversely proportional to each other. Such disadvantages may hinder the use of non-volatile memory as main memory. Even though the write latency itself is typically not critical to overall system performance, high-latency write requests can block access to the memory bank that contains the memory cells, which increases service time of read requests to that bank, leading to negative impact on performance. A conventional ReRAM controller, for example, conservatively uses a predefined and fixed write recovery time (tWR), which is based on the worst-case write latency that is only necessary when all bits are to be reset.

Other conventional ReRAM controllers seek to reduce the worst-case write latency by splitting a reset operation into a first phase where even bit-lines are reset, and a second phase where odd bit-lines are reset. By splitting a reset operation into two half-reset operations, the worst-case reset latency can be reduced since the worst-case write latency exponentially decreases as the number of bits to reset decreases. For example, two 4-bit resets would have less write latency than one 8-bit reset. However, the memory controller still considers the worst-case latency for each half-reset operation.

Accordingly, there is a need for an improved memory controller and method.

### BRIEF DESCRIPTION OF THE DRAWINGS

The embodiments will be more readily understood in view of the following description when accompanied by the below figures and wherein like reference numerals represent like elements.

FIG. 1 is a block diagram illustrating an example of an apparatus employing a memory controller that dynamically determines a variable reset latency time based on a data pattern of the data to be written into memory.

FIG. 2 is an illustration depicting an example of a data pattern of the data to be written into memory.

FIG. 3 is a flowchart generally illustrating an example of a method in a memory controller that dynamically determines a variable reset latency time based on a data pattern of the data to be written into memory.

FIG. 4 is a block diagram illustrating another example of an apparatus employing a memory controller that dynamically determines a variable reset latency time based on data patterns of the data to be written into memory and data currently in memory.

FIG. 5 is an illustration depicting another example of data patterns of the data to be written into memory and data currently in memory.

FIG. 6 is a flowchart generally illustrating an example of a method in a memory controller that dynamically determines a variable reset latency time based on a data pattern of the data to be written into memory and data currently in memory.

FIG. 7 is a block diagram illustrating an example of a system employing a memory controller that dynamically determines a variable reset latency time based on a data pattern of the data to be written into memory.

### DETAILED DESCRIPTION OF THE PREFERRED EMBODIMENTS

While this invention is susceptible of embodiments in many different forms, there is shown in the drawings and described herein in detail a specific embodiment with the understanding that the present disclosure is to be considered as an exemplification and is not intended to be limited to the embodiment illustrated.

It will be understood that like or analogous elements and/or components, referred to herein, may be identified throughout the drawings by like reference characters. In addition, it will be understood that the drawings are merely schematic representations of the invention, and some of the components may have been distorted from actual scale for purposes of pictorial clarity.

Briefly, in one example, an apparatus employing a memory controller that dynamically determines a variable reset latency time based on a data pattern of the data to be written into memory is disclosed. The apparatus may be a home media server, smart phone, tablet, other handheld computer, laptop computer, desktop computer, set-top box, content provider server, or any other suitable apparatus utilizing memory. The memory controller is communicatively coupled to a plurality of memory cells and a write request source configured to send a write request. The memory controller includes a variable reset latency determination logic configured to determine a variable reset latency time for the plurality of memory cells depending on the bit values to be written into the plurality of memory cells, in response to receiving the write request having corresponding bit values to be written into the plurality of memory cells. Write latency for the plurality of memory cells is dependent on the bit values being written into the plurality of memory cells. The memory controller is also configured to write the bit values of the write request to the plurality of memory cells within the determined variable reset latency time, for example, by sending a set and reset command to initiate a write operation at the plurality of memory cells using the determined variable reset latency time. During the write operation, the memory controller does not schedule any other read or write operations to or from those plurality of memory cells. Upon expiration of the determined variable reset latency time, the memory controller schedules additional read or write operations from or to those plurality of memory cells.

The variable reset latency determination logic determines the variable reset latency time by determining a number of bits having a specified bit value in the write request, such as “0,” and by determining the variable reset latency time based on the determined number of bits having the specified value.

In some embodiments, the variable reset latency determination logic determines the variable reset latency time by reading data from the plurality of memory cells, bitwise comparing the read data with the bit values to be written into the plurality of memory cells to determine bit locations in which the read data and the bit values to be written into the plurality of memory cells are different, determining a number of bits having a specified bit value in the write request among the determined bit locations, and determining the variable reset latency time based on the determined number of bits having the specified bit value.

A method in a memory controller that dynamically determines a variable reset latency time based on a data pattern of the data to be written into memory is also disclosed. More particularly, the method includes determining a variable reset latency time for the plurality of memory cells depending on the bit values to be written into the plurality of memory cells, in response to a write request having corresponding bit values to be written into a plurality of memory cells. A write latency for the plurality of memory cells is dependent on the bit values being written into the plurality of memory cells. The method further includes writing the bit values of the write request to the plurality of memory cells within the determined variable reset latency time, for example, by sending a set and reset command to initiate a write operation at the plurality of memory cells using the determined variable reset latency time. During the write operation, other read or write operations to or from those plurality of memory cells are not scheduled. Upon expiration of the determined variable reset latency time, additional read or write operations to or from those plurality of memory cells are scheduled.

The method determines the variable reset latency time by determining a number of bits having a specified bit value, such as “0,” in the write request and determining the variable reset latency time based on the determined number of bits having the specified value.

In some embodiments, the method determines the variable reset latency time by reading data from the plurality of memory cells, bitwise comparing the read data with the bit values to be written into the plurality of memory cells to determine bit locations in which the read data and the bit values to be written into the plurality of memory cells are different, determining a number of bits having a specified bit value in the write request among the determined bit locations, and determining the variable reset latency time based on the determined number of bits having the specified bit value.

Among other advantages, the memory controller in the embodiments described above exploits a super-linear relationship between the number of bits to reset and the reset latency. Instead of always using the worst-case reset latency, which is only necessary when all bits are to be reset, the memory controller can improve performance by taking advantage of the data pattern of the data to be written into memory, the correlation between currently stored data and data to be written, or both. The disclosed memory controller does not always use the worst-case latency, thereby assuming that not every bit needs to be reset, and instead, dynamically determines a variable reset latency time based on a data pattern of the data to be written into memory.

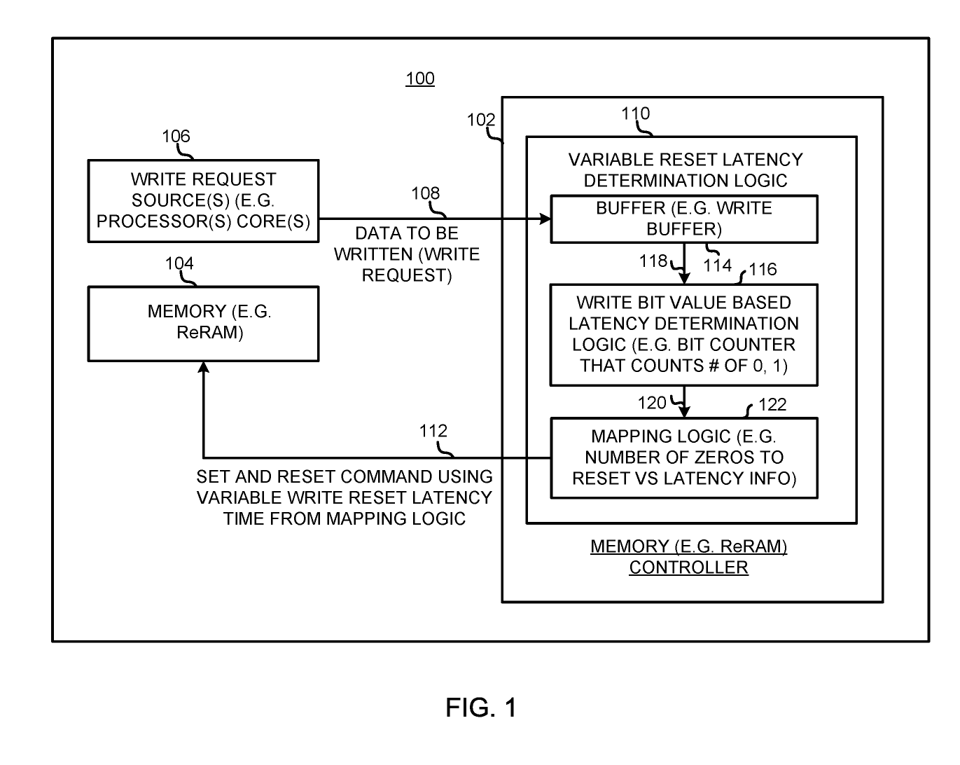

FIG. 1 is a block diagram illustrating an example of an apparatus 100 employing a memory controller 102 that dynamically determines a variable reset latency time based on a data pattern of the data to be written into memory 104. In this example, the apparatus 100 may be an integrated circuit that may be, for example, an APU, which as known in the art includes one or more CPU cores and one or more GPU cores on the same die. The integrated circuit may be in a home media server, smart phone, tablet, other handheld computer, laptop computer, desktop computer, set-top box, content provider server, etc. For purposes of illustration only, the apparatus 100 includes memory controller 102, memory 104 such as ReRAM, and a write request source 106 such as processor having processor core(s) (e.g., CPU core, GPU core). The memory controller 102 is communicatively coupled to a plurality of memory cells of memory 104 and a write request source 106 that is configured to send a write request 108 to the memory controller 102. The memory controller 102 may be any suitable executing software module, hardware, executing firmware or any suitable combination thereof, such as programmed processors, discrete logic, or state machines. The memory 104 may be any non-volatile memory, such as ReRAM, PCM, STT-RAM, or any other suitable non-volatile memory. Although FIG. 1 shows an example of a ReRAM controller to control ReRAM, memory controller 102 may be configured to control other types of non-volatile memory described above. The write request source 106 may be a specialized or general processor having multiple processing core(s). The processor may be programmable or a fixed hardware, such as an ALU, a CPU, a GPU, distributed processing circuitry, ASICs, state machines, discrete logic, or any other suitable processing circuitry known in the art.

The memory controller 102 also includes a variable reset latency determination logic 110 configured to determine a variable reset latency time for the plurality of memory cells depending on the bit values to be written into the plurality of memory cells, in response to receiving the write request 108 having corresponding bit values to be written into the plurality of memory cells of memory 104. Write latency for the plurality of memory cells is dependent on the bit values being written into the plurality of memory cells. For instance, there is a reset latency associated with resetting a bit to “0,” and a set latency associated with setting a bit to “1.” The memory controller 102 is configured to write the bit values of the write request to the plurality of memory cells within the variable reset latency time determined by the variable reset latency determination logic 110, for example, by sending a set and reset command 112 to initiate a write operation at the plurality of memory cells using the determined variable reset latency time. The variable reset latency determination logic 110 may be configured as a state machine, programmable or a fixed hardware, discrete logic, or any other suitable processing circuitry known in the art.

The variable reset latency determination logic 110 determines the variable reset latency time by determining a number of bits having a specified bit value in the write request 108, such as “0,” and by determining the variable reset latency time based on the determined number of bits having the specified value. Specifically, the variable reset latency determination logic 110 may include a buffer 114, such as a write buffer, that receives and stores the write request 108. The variable reset latency determination logic 110 also includes a write bit value based latency determination logic 116, such as a bit counter, that receives the write request 118 from the buffer 114 and counts the number of bits having the specified value, such as “0,” in the write request 108. In other embodiments, the write bit value based latency determination logic 110 is configured to count the number of bits having a value of “1” in the write request 108. The variable reset latency determination logic 110 sends the count value via communication link 120 to mapping logic 122 to determine the variable reset latency time based on the count value. The mapping logic 122 may be a state machine, look up table, programmable or a fixed hardware, discrete logic, or any other suitable processing circuitry known in the art that effectively maps a specific variable reset latency time to a specific count value. The mapping logic 122 then retrieves the specific variable reset latency time corresponding to the specific count value.

Subsequently, the memory controller 102 generates the set and reset command 112 based on the variable reset latency time obtained from the mapping logic 122. Accordingly, memory controller 102 writes the bit values of the write request 108 to a memory bank of memory 104 within the variable reset latency time. The memory controller 102 also uses the variable reset latency time to preclude scheduling any other read or write operations to or from the same memory bank of memory 104 within the retrieved variable reset latency time. Upon expiration of the retrieved variable reset latency time, the memory controller schedules additional read or write operations from or to the same memory bank in memory 104.

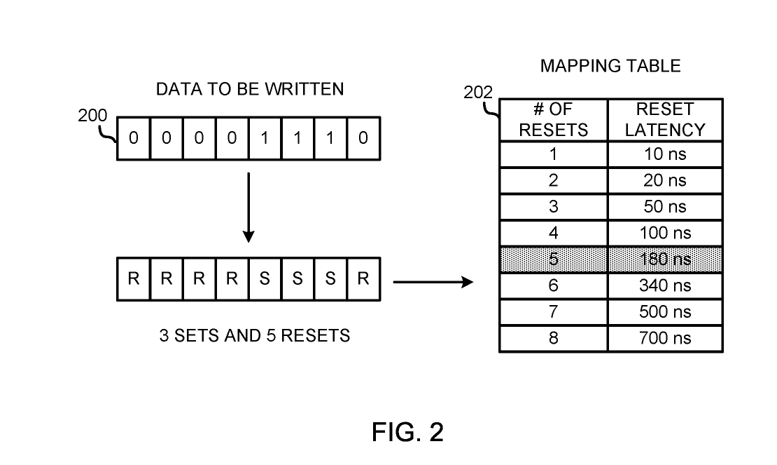

By way of example, as shown in FIG. 2, the write request 108 may comprise the bitstream 200 having the value “00001110” to be written into memory 104. The buffer 114 receives and stores the write request 108, and subsequently, the write bit value based latency determination logic 116 receives the write request 108 from the buffer 114 via communication link 118 and proceeds to count the number of bits having a specified value, such as “0.” The write bit value based latency determination logic 116, after determining that there are five “0s” (i.e., five resets) in the bitstream “00001110,” then sends the count value or equivalent of “5” via communication link 120 to the mapping logic 122 to determine the variable reset latency time based on the count value. For instance, the mapping logic 122 may be a circuit that is programmed with an algorithm that determines the variable reset latency time based on the count value. If the algorithm comprises multiplying the count value by a set factor, such as “10 ns,” the count value of “5” would produce “50 ns” as the specific variable reset latency time that corresponds to the count value or equivalent of “5.”.

In other embodiments, the mapping logic 122 may utilize the mapping table 202 as shown in FIG. 2 that has a predetermined mapping of a specific variable reset latency time that corresponds to the count value or equivalent of “5.” The mapping logic 122 may retrieve “180 ns” from the mapping table 202 as the specific variable reset latency time that corresponds to the count value or equivalent of “5.” The memory controller 102 may then generate the set and reset command 112 associated with “180 ns” determined by the mapping logic 122. Accordingly, the memory controller 102 may write the bit values of the write request 108 to a memory bank of memory 104 within the variable reset latency time. During the reset operation, memory controller 102 does not schedule any other read or write operation from or to the same memory bank of memory 104 for a duration of “180 ns.” Although FIG. 2 depicts mapping table 202 calibrated with variable reset latency times, one of ordinary skill in the art will understand that the mapping table 202 may be calibrated with variable set latency time values so that apparatus 100 may be configured to count the number of bits of the write request 108 having a specified value of “1.” Such calibration will allow the write bit value based latency determination logic 116 to determine that there are three “1s” (i.e., three sets) in the bitstream “00001110,” and may then send the count value or equivalent of “3” via communication link 120 to the mapping logic 122.

In addition, coding techniques may be applied to the write request 108 in order to reduce the number of bits having a specified bit value to be written into memory 104. For instance, because the bitstream 200 having the value “00001110” has more “0s” than “1s,” which leads to higher reset latency, the variable reset latency determination logic utilizes an inverting coding technique that inverts bitstream 200 such that the write bit value based latency determination logic 116 determines that there are three “0s” (i.e., three resets) in the inverted bitstream “11110001.” The write bit value based latency determination logic 116 then sends the count value or equivalent of “3,” along with additional metadata information (e.g., a one-bit flag) indicating whether the bitstream is in native or coded form, to the mapping logic 122 via communication link 120 to determine the variable reset latency time based on the count value. Upon receiving and decoding the coded bitstream, the mapping logic 122 retrieves “50 ns” from the mapping table 202 as the specific variable reset latency time that corresponds to the count value or equivalent of “3.”

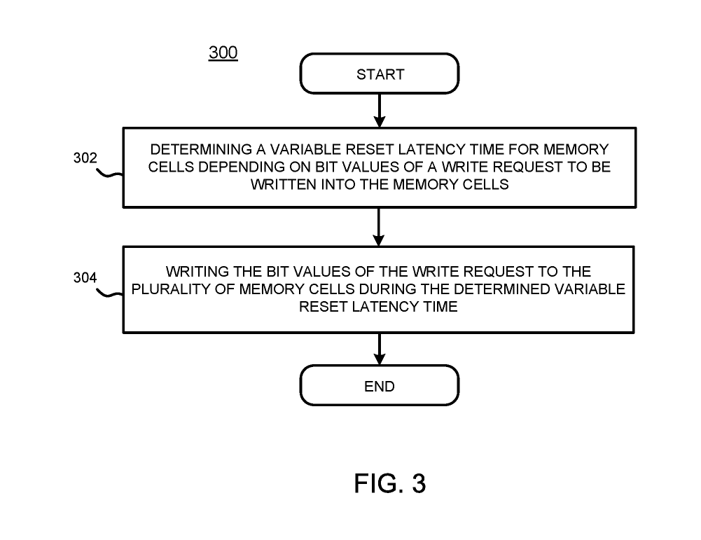

FIG. 3 is a flowchart 300 generally illustrating an example of a method in a memory controller that dynamically determines a variable reset latency time based on a data pattern of the data to be written into memory. As shown in block 302, the method includes determining a variable reset latency time for memory cells depending on the bit values to be written into the memory cells. The variable reset latency time is determined in response to a write request having corresponding bit values to be written into a plurality of memory cells, where a write latency for the plurality of memory cells is dependent on the bit values being written into the plurality of memory cells. Block 302 may be performed, for example, by the variable reset latency determination logic 110 of the memory controller 102 of FIG. 1 upon receiving write request 108. As shown in block 304, the method includes writing the bit values of the write request to the plurality of memory cells within the determined variable reset latency time. Block 304 may be performed, for example, by the memory controller 102 of FIG. 1 using the variable reset latency time obtained from the mapping logic 122.

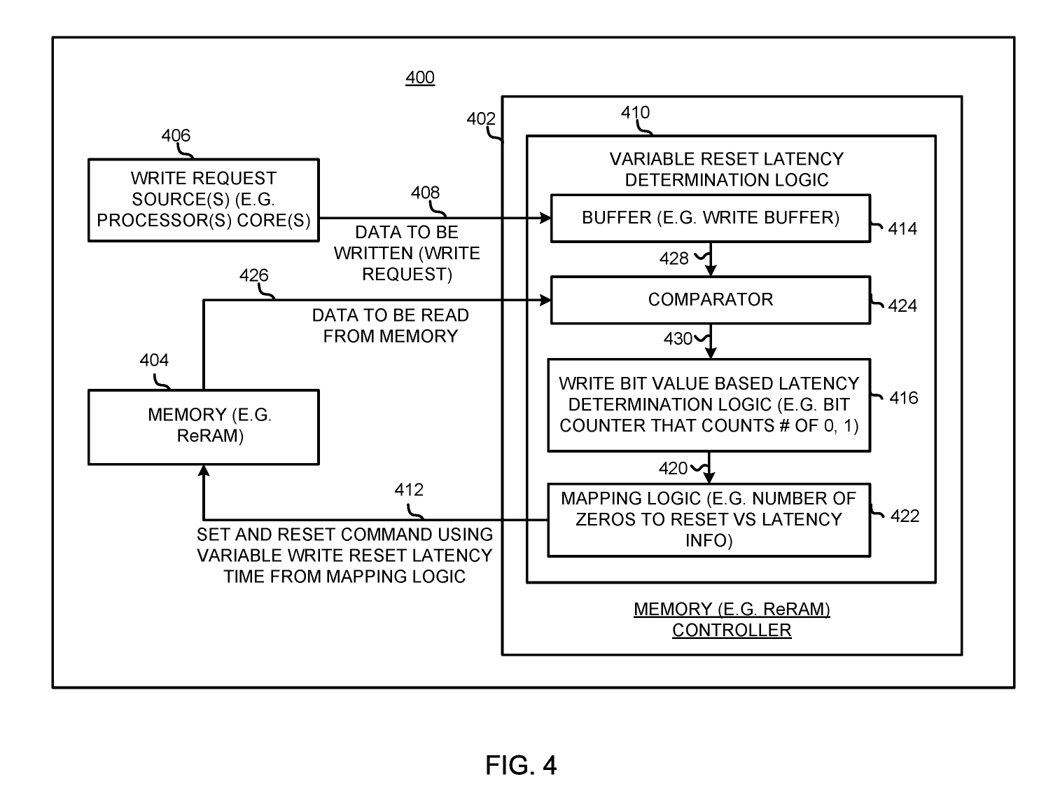

FIG. 4 is a block diagram illustrating another example of an apparatus 400 employing a memory controller 402 that dynamically determines a variable reset latency time based on data patterns of the data to be written into memory 404 and data currently in memory 404. The memory controller 402 is communicatively coupled to a plurality of memory cells of memory 404 and a write request source 406 that is configured to send a write request 408 to the memory controller 402.

The memory controller 402 includes a variable reset latency determination logic 410 configured to determine a variable reset latency time for the plurality of memory cells depending on the bit values to be written into the plurality of memory cells, in response to receiving the write request 408 having corresponding bit values to be written into the plurality of memory cells. Write latency for the plurality of memory cells is dependent on the bit values being written into the plurality of memory cells. The memory controller 402 is also configured to write the bit values of the write request to the plurality of memory cells within the variable reset latency time determined by the variable reset latency determination logic 410, for example, by sending a set and reset command 412 to initiate a write operation at the plurality of memory cells using the determined variable reset latency time.

The variable reset latency determination logic 410 determines the variable reset latency time by reading data 426 from the plurality of memory cells of memory 404; bitwise comparing the read data 426 with the bit values of the write request 408 to be written into the plurality of memory cells to determine bit locations in which the read data 426 and the write request 408 are different; determining a number of bits having a specified bit value, such as “0,” in the write request 408 among the determined bit locations; and determining the variable reset latency time based on the determined number of bits having the specified bit value. Specifically, the variable reset latency determination logic 410 includes a buffer 414, such as a write buffer, that receives and stores the write request 408. The variable reset latency determination logic 410 also includes a comparator 424 that receives data 426 to be read from memory 404 and the write request 428 from the buffer 414 to bitwise compare the read data 426 and write request 408. Accordingly, the comparator 424 determines bit locations in which the read data 426 and the write request 408 are different. Although not shown, the variable reset latency determination logic 410 utilizes another buffer to receive and store data 426 from memory 404, so that the comparator 424 can retrieve the read data 426 stored in such buffer. To limit the number of reads from memory 404, additional buffers or caches may be contemplated to store copies of data stored in recently accessed locations or rows in memory 404.

The variable reset latency determination logic 410 also includes a write bit value based latency determination logic 416, such as a bit counter, that receives the output 430 from the comparator 424 indicative of the determined bit locations and corresponding bit values in the write request 408 in which the read data 426 and the write request 408 are different, and counts the number of bits having the specified value, such as “0,” among the determined bit locations in the write request 408. In other embodiments, the write bit value based latency determination logic 410 is configured to count the number of bits having a value of “1” in the write request 408. The variable reset latency determination logic 410 sends the count value via communication link 420 to mapping logic 422 to determine the variable reset latency time based on the count value. The mapping logic 422 retrieves the specific variable reset latency time corresponding to the specific count value. The memory controller 402 then generates the set and reset command 412 using the variable reset latency time obtained from the mapping logic 422. Accordingly, the memory controller 402 writes the bit values of the write request 408 to a memory bank of memory 404 within the variable reset latency time.

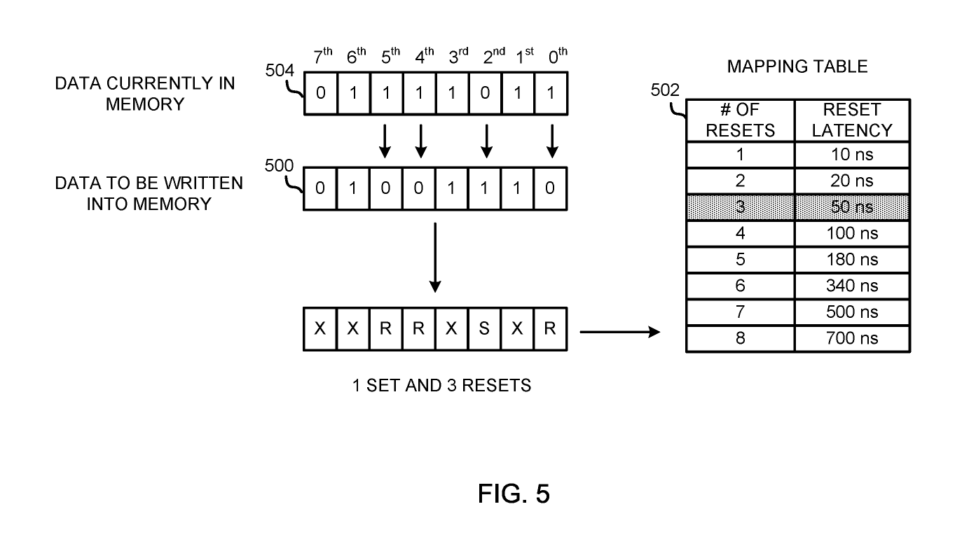

By way of example, as shown in FIG. 5, the write request 408 may include the bitstream 500 having the value “01001110” to be written into memory 404. The buffer 414 receives and stores the write request 408. Read data 426 may include the bitstream 504 having the value “01111011” currently stored in memory 404 and read from memory 404. The comparator 424 receives the read data 426 and write request 408 from the buffer 414 to bitwise compare the read data 426 to determine bit locations in which the read data 426 and the write request 408 are different. Comparator 424 determines that the read data 426 and the write request 408 have different bit values in the 0^{th}, 2^{nd}, 4^{th}, and 5^{th} bit locations. The comparator 430 provides the 0^{th}, 2^{nd}, 4^{th}, and 5^{th} bit locations and corresponding bit values in the write request 408 as output 430 to the write bit value based latency determination logic 416, which counts the number of bits having the specified value, such as “0,” among the determined bit locations in the write request 408. The write bit value based latency determination logic 416, after determining that there are three “0s” (i.e. three resets) among the 0^{th}, 2^{nd}, 4^{th}, and 5^{th} bit locations of bitstream “01001110,” then sends the count value or equivalent of “3” via communication link 420 to the mapping logic 422 to determine the variable reset latency time based on the count value. For instance, the mapping logic 422 may be a circuit that is programmed with an algorithm that determines the variable reset latency time based on the count value. If the algorithm comprises multiplying the count value by a set factor, such as “10 ns,” the count value of “3” would produce “30 ns” as the specific variable reset latency time that corresponds to the count value or equivalent of “3.”

In other embodiments, the mapping logic 422 may utilize the mapping table 502 as shown in FIG. 5 that has a predetermined mapping of a specific variable reset latency time that corresponds to the count value or equivalent of “3.” The mapping logic 422 may retrieve “50 ns” from the mapping table 502 as the specific variable reset latency time that corresponds to the count value or equivalent of “3.” The memory controller 402 then generates the set and reset command 412 associated with “50 ns” determined by the mapping logic 422. Accordingly, the memory controller 402 writes the bit values of the write request 408 to a memory bank of memory 404 within the variable reset latency time. During the reset operation, memory controller 402 does not schedule any other read or write operation to or from the same memory bank of memory 404 for a duration of “50 ns.” Although FIG. 5 depicts mapping table 502 calibrated with variable reset latency times, one of ordinary skill in the art will understand that the mapping table 502 may be calibrated with variable set latency times so that apparatus 400 may be configured to count the number of bits of the write request 408 having a specified value of “1.” Such calibration will allow the write bit value based latency determination logic 416 to determine that there is one “1” (i.e., one set) among the 0^{th}, 2^{nd}, 4^{th}, and 5^{th} bit locations of bitstream “01001110,” and may then send the count value or equivalent of “1” via communication link 420 to the mapping logic 422.

The embodiments described above may utilize one or more coding techniques that can reduce the number of zeros to be written (e.g., inverting the data if more than 50% of the bits are zeros and storing metadata to indicate whether the data is stored in native or coded form). For example, coding techniques may be applied to the write request 408 in order to reduce the number of bits having a specified bit value to be written into memory 404. For instance, if bitstream 500 contains the value “00001110,” the variable reset latency determination logic 410 utilizes an inverting coding technique that inverts bitstream 500 to “11110001.” Comparator 424 may compare each of the original bitstream and inverted bitstream with read data 426 to be read from memory 404, to determine bit locations in which the read data 426 and both original bitstream and inverted bitstream are different.

If, for example, read data 426 contains the value “01111011,” comparator 424 determines that the original bitstream of “00001110” and read data 426 have different bit values in the 0^{th}, 2^{nd}, 4^{th}, 5^{th}, and 6^{th} bit locations, and write bit value based latency determination logic 416 counts four bits having a specified value, such as “0,” among the determined bit locations in the original bitstream. Similarly, comparator 424 determines that the inverted bitstream of “11110001” and read data 426 “01111011,” have different bit values in the 1^{st} 3^{rd} and 7th bit locations, and write bit value based latency determination logic 416 counts two bits having a specified value, such as “0,” among the determined bit locations in the inverted bitstream.

The write bit value based latency determination logic 416 may further determine that the number of bits having a value of “0” among the determined bit locations in the original bitstream is greater than the number of bits having a value of “0” among the determined bit locations in the inverted bitstream, and thus send the number of bits (i.e., two) having a value of “0” among the determined bit locations in the inverted bitstream as the count value or equivalent via communication link 420 to the mapping logic 422 to determine the variable reset latency time based on the count value. Accordingly, instead of the mapping logic 422 retrieving “100 ns” that corresponds to the count value or equivalent of “4” had there been no coding technique applied, the mapping logic 422 may retrieve “20 ns,” which corresponds to the count value associated with the inverted bitstream.

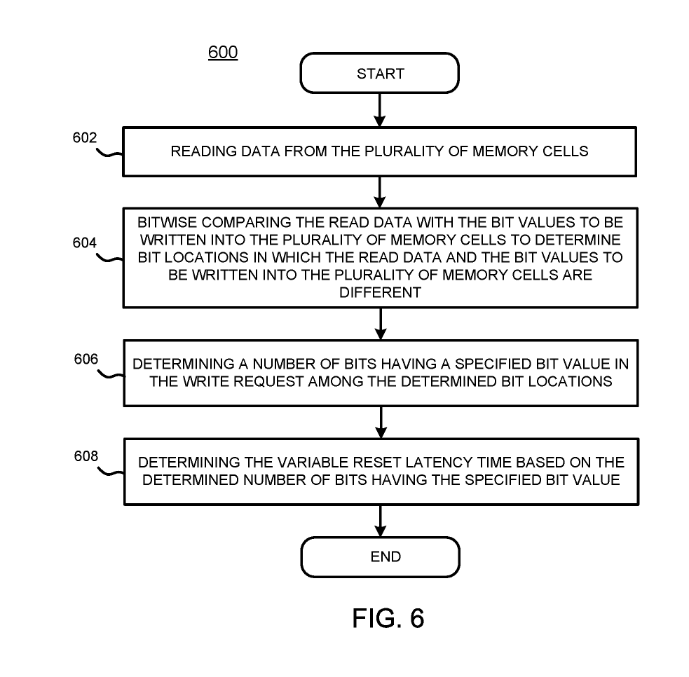

FIG. 6 is a flowchart 600 generally illustrating an example of a method in a memory controller that dynamically determines a variable reset latency time based on a data pattern of the data to be written into memory and data currently in memory. As shown in block 602, the method includes reading data from the plurality of memory cells. Block 602 may be performed, for example, by the variable reset latency determination logic 410 of the memory controller 402 of FIG. 4. As shown in block 604, the method includes bitwise comparing the read data with the bit values to be written into the plurality of memory cells to determine bit locations in which the read data and the bit values to be written into the plurality of memory cells are different. Block 604 may be performed, for example, by the variable reset latency determination logic 410 of the memory controller 402, and specifically, comparator 424 of FIG. 4. As shown in block 606, the method includes determining a number of bits having a specified bit value in the write request among the determined bit locations. Block 606 may be performed, for example, by the variable reset latency determination logic 410 of the memory controller 402, and specifically, write bit value based latency determination logic 416 of FIG. 4. As shown in block 608, the method includes determining the variable reset latency time based on the determined number of bits having the specified bit value. Block 608 may be performed, for example, by the variable reset latency determination logic 410 of the memory controller 402, and specifically, the mapping logic 422 of FIG. 4.

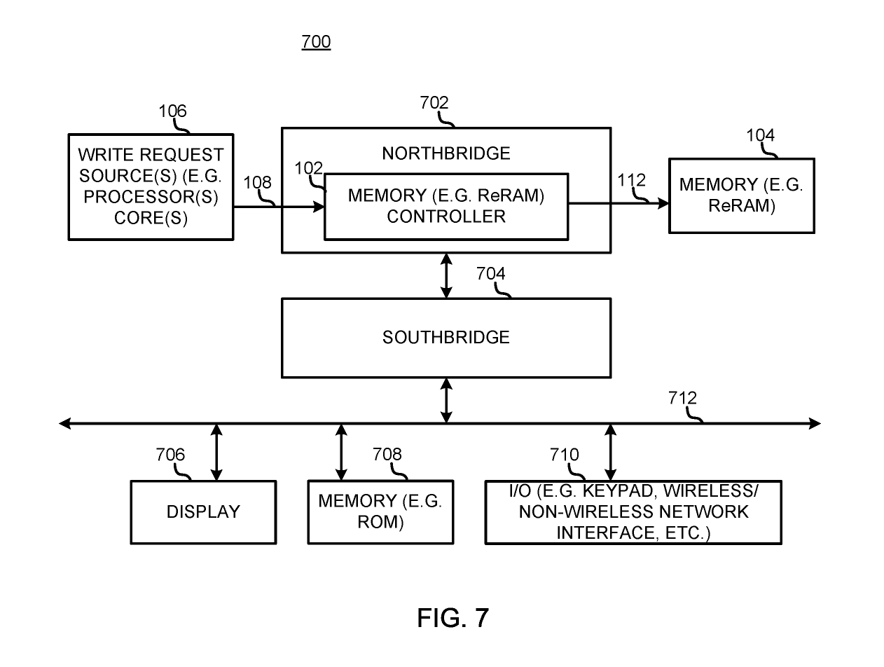

FIG. 7 is a block diagram illustrating an example of an apparatus, such as chipset 700, employing a memory controller 102 that dynamically determines a variable reset latency time based on a data pattern of the data to be written into memory 104. The chipset 700 may be in a home media server, smart phone, tablet, other handheld computer, laptop computer, desktop computer, set-top box, content provider server, etc. Specifically, the chipset 700 includes a northbridge 702, which includes memory controller 102, and southbridge 704. The northbridge 702 handles communication among, inter alia, the write request source 106, memory 104, and the southbridge 704. The southbridge 704 handles communication among the memory 708, such as Read-Only Memory (ROM), display 706, and other peripheral devices, such as a keypad, wireless or non-wireless network interface, etc. Although the memory controller 102 is located within the northbridge 702, it may be integrated on the same single integrated circuit die as the write request source 106. Similarly, memory 104 may be integrated on the same single integrated circuit die as the write request source 106. Communication paths interconnecting the various components in FIG. 7, such as path 712, may be implemented using any suitable protocols, such as PCI (Peripheral Component Interconnect), PCI-Express, AGP (Accelerated Graphics Port), HyperTransport, or any other bus or point-to-point communication protocol(s), and connections between different devices may use different protocols as is known in the art.

The memory controller in the embodiments described above exploits a super-linear relationship between the number of bits to reset and reset latency. Instead of always using the worst-case reset latency, which is only necessary when all bits are to be reset, the memory controller can improve performance by taking advantage of the data pattern of the data to be written into memory, the correlation between currently stored data and data to be written, or both. Although the disclosure above provides embodiments of a ReRAM controller, the general methodology is applicable to any non-volatile memory type whose latency varies based on the data being written.

The foregoing description merely explains and illustrates the invention and the invention is not limited thereto except insofar as the appended claims are so limited, as those skilled in the art who have the disclosure before them will be able to make modifications without departing from the scope of the invention.

What is claimed is:

1. A method, carried out by a memory controller, the method comprising:
determining a variable reset latency time for a plurality of memory cells depending on bit values to be written into a plurality of memory cells, in response to a write request having the corresponding bit values, wherein a write latency for the plurality of memory cells is dependent on the bit values being written into the plurality of memory cells; and
writing the bit values of the write request to the plurality of memory cells within the determined variable reset latency time.

2. The method of claim 1, wherein the determining of the variable reset latency time further comprises:
determining a number of bits having a specified bit value in the write request; and
determining the variable reset latency time based on the determined number of bits having the specified value.

3. The method of claim 2, wherein the determining of the variable reset latency time based on the determined number of bits having the specified value comprises utilizing a mapping logic that maps a specific variable reset latency time to the determined number of bits having the specified value.

4. The method of claim 2, wherein the specified bit value is 0.

5. The method of claim 1, wherein the determining of the variable reset latency time further comprises:
reading data from the plurality of memory cells;
bitwise comparing the read data with the bit values to be written into the plurality of memory cells to determine bit locations in which the read data and the bit values to be written into the plurality of memory cells are different;
determining a number of bits having a specified bit value in the write request among the determined bit locations; and
determining the variable reset latency time based on the determined number of bits having the specified bit value.

6. The method of claim 1, wherein writing the bit values of the write request to the plurality of memory cells comprises sending a set and reset command to the plurality of memory cells.

7. The method of claim 1, wherein the determining of the variable reset latency time further comprises:
applying a coding technique to the write request;
determining a number of bits having a specified bit value in the coded write request; and
determining the variable reset latency time based on the determined number of bits having the specified value.

8. A memory controller comprising:
a variable reset latency determination logic configured to:
determine a variable reset latency time for a plurality of memory cells depending on the bit values to be written into a plurality of memory cells in response to a write request having corresponding bit values, wherein a write latency for the plurality of memory cells is dependent on the bit values being written into the plurality of memory cells; and
write the bit values of the write request to the plurality of memory cells within the determined variable reset latency time.

9. The memory controller of claim 8, wherein the variable reset latency determination logic determines the variable reset latency time by:
determining a number of bits having a specified bit value in the write request; and
determining the variable reset latency time based on the determined number of bits having the specified value.

10. The memory controller of claim 9, wherein the determining of the variable reset latency time based on the determined number of bits having the specified value comprises utilizing mapping logic that maps a specific variable reset latency time to the determined number of bits having the specified value.

11. The memory controller of claim 9, wherein the specified bit value is 0.

12. The memory controller of claim 8, wherein the variable reset latency determination logic further determines the variable reset latency time by:
reading data from the plurality of memory cells;
bitwise comparing the read data with the bit values to be written into the plurality of memory cells to determine bit locations in which the read data and the bit values to be written into the plurality of memory cells are different;
determining a number of bits having a specified bit value in the write request among the determined bit locations; and
determining the variable reset latency time based on the determined number of bits having the specified bit value.

13. The memory controller of claim 8, wherein the memory controller writes the bit values of the write request to the plurality of memory cells by sending a set and reset command to the plurality of memory cells.

14. The memory controller of claim 8, wherein the variable reset latency determination logic determines the variable reset latency time by:
applying a coding technique to the write request;
determining a number of bits having a specified bit value in the coded write request; and
determining the variable reset latency time based on the determined number of bits having the specified value.

15. An apparatus comprising:
a plurality of memory cells;
a write request source configured to send a write request;
a memory controller communicatively coupled to the plurality of memory cells and the write request source, the memory controller comprising:
a variable reset latency determination logic configured to:
determine a variable reset latency time for the plurality of memory cells depending on bit values to be written into the plurality of memory cells, in response to receiving the write request having the corresponding bit values, wherein a write latency for the plurality of memory cells is dependent on the bit values being written into the plurality of memory cells; and
write the bit values of the write request to the plurality of memory cells within the determined variable reset latency time.

16. The apparatus of claim 15, wherein the variable reset latency determination logic determines the variable reset latency time by:
determining a number of bits having a specified bit value in the write request; and
determining the variable reset latency time based on the determined number of bits having the specified value.

17. The apparatus of claim 16, wherein the determining of the variable reset latency time based on the determined number of bits having the specified value comprises utilizing mapping logic that maps a specific variable reset latency time to the determined number of bits having the specified value.

18. The apparatus of claim 15, wherein the variable reset latency determination logic further determines the variable reset latency time by:
reading data from the plurality of memory cells;
bitwise comparing the read data with the bit values to be written into the plurality of memory cells to determine bit locations in which the read data and the bit values to be written into the plurality of memory cells are different;
determining a number of bits having a specified bit value in the write request among the determined bit locations; and
determining the variable reset latency time based on the determined number of bits having the specified bit value.

19. The apparatus of claim 15, wherein the memory controller writes the bit values of the write request to the plurality of memory cells by sending a set and reset command to the plurality of memory cells.

20. The apparatus of claim 15, further comprising a display and at least one peripheral device.
